(19) United States
(12) Patent Application Publication
(10) Pub. No.: US 2026/0180550 A1
(43) Pub. Date: Jun. 25, 2026

(54) METHOD FOR DESIGNING SAW RESONATOR AND COMPUTING DEVICE-READABLE RECORDING MEDIUM ON WHICH METHOD IS RECORDED

(71) Applicant: WiPAM, Inc., Seongnam-si, Gyeonggi-do (KR)

(72) Inventors: Dae Kyu YU, Seoul (KR); Kyoung Joon MIN, Seongnam-si, Gyeonggi-do (KR); Kyung Oh KIM, Seoul (KR)

(73) Assignee: WiPAM, Inc., Seongnam-si, Gyeonggi-do (KR)

(21) Appl. No.: 18/725,805

(22) PCT Filed: Dec. 15, 2022
(86) PCT No.: PCT/KR2022/020438

§ 371 Date: Jun. 30, 2024

(30) Foreign Application Priority Data
Dec. 29, 2021 (KR) 10-2021-0190776

(51) Int. Cl. H03H 9/145; H03H 9/02; H03H 9/72

(52) U.S. Cl. CPC H03H 9/14567; H03H 9/02559; H03H 9/02574; H03H 9/02834; H03H 9/02866; H03H 9/02992; H03H 9/14582; H03H 9/14594; H03H 9/725

(57) ABSTRACT

The present invention is for providing a method for designing an SAW resonator and a computing device-readable recording medium on which the method is recorded, wherein, instead of directly measuring characteristics of SAW of the SAW resonator, a 4-port transmission line model for an SAW IDT electrode is established, and parameters of the 4-port transmission line model are calculated by using an initial parameter measured from a sample of the SAW resonator, thereby configuring an SAW filter over a wide frequency band from hundreds of MHz to several GHz.

### TECHNICAL FIELD

The present invention relates to a SAW resonator design method of designing a SAW resonator, which is a resonator or a band-pass filter used in mobile communication devices and the like, the SAW resonator being configured to convert an electrical signal into a surface acoustic wave (SAW) of a piezoelectric material using the piezoelectric effect of the piezoelectric material and to convert the converted surface acoustic wave (SAW) back into an electrical signal, using the parameters of a four-port equivalent circuit model of a SAW IDT, such as the IDT electrode capacitance, the SAW phase velocity, the electromechanical coupling coefficient, and the attenuation constant of an IDT electrode, and a computing device-readable recording medium having the same recorded thereon.

### BACKGROUND ART

In recent years, a solid piezoelectric material has been widely used in radio frequency (RF) electronic systems because the acoustic wave in the material can be well controlled by the physical layout of the surface.

In particular, an RF filter based on an acoustic resonator is an important circuit component of a microwave integrated system due to high performance, miniaturization, and low cost thereof.

When a time-varying electrical signal is applied to an IDT electrode of a SAW resonator, particles in an elastic material vibrate. As a result, the acoustic wave is generated on the shallow surface of a piezoelectric substrate.

Physical phenomena related to the IDT electrode provided at the piezoelectric substrate of the SAW resonator are too complex to understand the operation mechanism of the SAW resonator because the electromagnetic wave is intertwined with the acoustic wave.

In the SAW resonator, the electromagnetic wave and the acoustic wave may be treated as separate waves by introducing the electromechanical coupling coefficient (k²), which indicates how much electrical energy can be converted into acoustic energy.

In Prior Art Document 1 (W. R. Smith, H. M. Gerard, J. H. Collins, T. M. Reeder, and H. J. Shaw, “Analysis of Interdigital Surface Wave Transducers by Use of an Equivalent Circuit Model” IEEE Trans. Microw. Theory Tech., Vol. MTT-17, no. 11, pp. 856-864, November 1969.) and Prior Art Document 2 (W. R. Smith, H. M. Gerard, and W. R. Jones, “Analysis and Design of Dispersive Interdigital Surface-Wave Transducers” IEEE Trans. Microw, Theory Tech., Vol. MTT-20, no. 7, pp. 458-471, July 1972.), Smith modeled a SAW device as an electrically and mechanically coupled four-port distributed circuit capable of mathematically formulating the physical properties of a surface acoustic wave (SAW) in an IDT electrode using the electromechanical coupling coefficient, the acoustic phase velocity, and the acoustic energy loss, which facilitated understanding of the physical properties of the surface acoustic wave (SAW) generated in the IDT electrode.

However,

$${k}_{bulk}^{2} ( \approx 2 \frac{∇ {v}_{a}}{{v}_{a}} )$$

theoretically determined in a bulk piezoelectric material may have a large deviation in real devices.

Here, vₐ is the phase velocity of the acoustic wave in the piezoelectric material. For bulk acoustic wave (BAW) devices, the theoretically determined k²_{bulk} is accurate enough, but for SAW devices, most of the acoustic energy is distributed on the surface of the piezoelectric substrate, and therefore k² from a bulk device model is not suitable for application to the SAW devices.

Meanwhile, in Prior Art Document 3 (O. Ikata, T. Miyashita, T. Matsuda, T. Nishihara and Y. Satoh, “Development of low-loss band-pass filters using SAW resonator for portable telephones,” in Proc. IEEE Ultrason. Symp., 1992, pp. 111-115.), Ikata determined k² such that the bandwidth of a filter was consistent with the experimental results using experimental data.

Ikata then divided the interior of an IDT electrode into a metal region and an empty space region considering the metal loading effect of the IDT electrode to distinguish between acoustic wave phase velocities vₒ and vₘ in the two regions.

These parameters are reasonably accurate up to hundreds of MHz, but are not accurate enough for a frequency band of several GHz, which may lead to significant design failure in SAW IDT-based microwave circuit design using this conventional technology.

[Prior art Document 1] W. R. Smith, H. M. Gerard, J. H. Collins, T. M. Reeder, and H. J. Shaw, “Analysis of Interdigital Surface Wave Transducers by Use of an Equivalent Circuit Model” IEEE Trans. Microw. Theory Tech., Vol. MTT-17, no. 11, pp. 856-864, November 1969.

[Prior art Document 2] W. R. Smith, H. M. Gerard, and W. R. Jones, “Analysis and Design of Dispersive Interdigital Surface-Wave Transducers” IEEE Trans. Microw, Theory Tech., Vol. MTT-20, no. 7, pp. 458-471, July 1972.

[Prior art Document 3] O. Ikata, T. Miyashita, T. Matsuda, T. Nishihara, and Y. Satoh, “Development of low-loss band-pass filters using SAW resonator for portable telephones” in Proc. IEEE Ultrason. Symp., 1992, pp. 111-115.

### DISCLOSURE

### Technical Problem

It is an object of the present invention to provide a SAW resonator design method capable of establishing a four-port transmission line model for a SAW IDT electrode, calculating the parameters of the four-port transmission line model using the initial parameters measured from the sample of a SAW resonator, and configuring a SAW filter over a wide frequency band from hundreds of MHz to several GHz therefrom, instead of directly measuring the characteristics of a SAW of the SAW resonator, and a computing device-readable recording medium having the same recorded thereon.

### Technical Solution

A SAW resonator design method using characteristic information of a SAW resonator according to an embodiment of the present invention includes calculating feature frequency information for a surface acoustic wave generated by an IDT electrode using a scattering coefficient measured from each of SAW resonator samples, calculating information indicative of physical properties of the surface acoustic wave in the IDT electrode using the feature frequency information, and designing a SAW resonator from a transmission line circuit model of the surface acoustic wave using the calculated information indicative of the physical properties of the surface acoustic wave.

The SAW resonator design method may further include calculating the capacitance per finger of the IDT electrode using the scattering coefficient as one piece of the information indicative of the physical properties of the surface acoustic wave.

The step of calculating the feature frequency information for the surface acoustic wave may include calculating the resonance frequency, the anti-resonance frequency, and the spurious response frequency for the surface acoustic wave generated by the IDT electrode using the impedance or the admittance of the IDT electrode converted from the scattering coefficient.

The step of calculating the information indicative of the physical properties of the surface acoustic wave may include determining the phase velocity of the surface acoustic wave in the IDT electrode using the feature frequency information, determining the electromechanical coupling coefficient indicative of how much electrical energy can be converted into surface acoustic wave energy from the IDT electrode using the feature frequency information and determining the attenuation constant of the surface acoustic wave in the IDT electrode using the feature frequency information.

The step of calculating the information indicative of the physical properties of the surface acoustic wave may include determining a temporary value as the value of the phase velocity indicative of the physical properties of the surface acoustic wave when frequency characteristics calculated by repeatedly applying the temporary value to the phase velocity of the surface acoustic wave in the IDT electrode while varying the temporary value approach the calculated resonance frequency and the calculated spurious response frequency within a predetermined range.

The step of calculating the information indicative of the physical properties of the surface acoustic wave may include determining a temporary value as the value of an electromechanical coupling coefficient indicative of the physical properties of the surface acoustic wave when frequency characteristics calculated by repeatedly applying the temporary value to the electromechanical coupling coefficient of the IDT electrode while varying the temporary value approach the calculated anti-resonance frequency within a predetermined range.

The step of calculating the information indicative of the physical properties of the surface acoustic wave may include determining the attenuation constant such that peak-to-peak magnitudes of the resonance frequency and the anti-resonance frequency of the impedance or the admittance of the IDT electrode are consistent with peak-to-peak magnitudes of the calculated resonance frequency and the calculated anti-resonance frequency.

Meanwhile, the present invention provides a computing device-readable recording medium having the SAW resonator design method recorded thereon.

### Advantageous Effects

The SAW resonator design method according to the present invention and the recording medium readable by the computing device recording the same have the effect of establishing a four-port transmission line model for a SAW IDT electrode, calculating the parameters of the four-port transmission line model using the initial parameters measured from the sample of a SAW resonator, and configuring a SAW filter over a wide frequency band from hundreds of MHz to several GHz therefrom, instead of directly measuring the characteristics of a SAW of the SAW resonator.

### DESCRIPTION OF DRAWINGS

FIG. 1 illustrates a view (a) showing a one-port SAW resonator, and a view (b) showing the mechanism for an IDT electrode of the SAW resonator as an equivalent electrical circuit in order to analyze the physical properties of a surface acoustic wave (SAW) generated through the IDT electrode of the SAW resonator shown in the view (a).

FIG. 2 illustrates an enlarged view (a) showing the IDT electrode 200 of the SAW resonator, and a view (b) showing a four-port transmission line model using an equivalent electrical circuit based on an i-th finger for analysis of the SAW by the IDT electrode shown in the enlarged view (a).

FIG. 3 is a flowchart illustrating steps of a SAW resonator design method according to an embodiment of the present invention.

FIG. 4 is a view showing one example of calculating the capacitance for the IDT electrode of the SAW resonator using a 3D field solver.

FIG. 5 is a graph showing the admittance Yᵢₙ as a function of the frequency of the IDT electrode of the SAW resonator, wherein a resonance frequency f₁, an anti-resonance frequency f₂, and a spurious response frequency f₃ are shown.

FIG. 6 is a graph showing the relationship between the SAW phase speed, the phase speed ratio, and the film-thickness ratio h/Lₚ obtained according to an embodiment of the present invention.

FIG. 7 is a graph showing the relationship between the electromechanical coupling coefficient k², and the attenuation constant α, and the film-thickness ratio h/Lₚ obtained according to an embodiment of the present invention.

FIG. 8 illustrates a view (a) showing a 3.5-stage ladder type SAW filter manufactured to verify the SAW resonator design method according to the embodiment of the present invention, and a graph (b) showing frequency versus insertion loss for the test SAW filter shown in the view (a).

### BEST MODE

A SAW resonator design method according to the present invention and a computing device-readable recording medium having the same recorded thereon will now be described in detail with reference to the accompanying drawings.

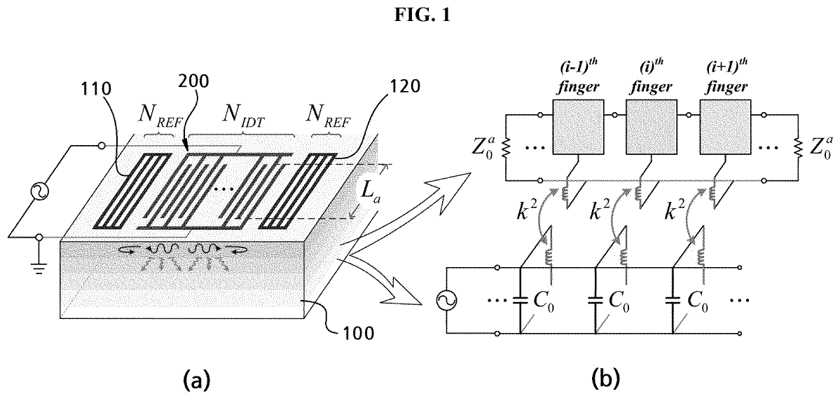

FIG. 1(a) is a view showing a one-port SAW resonator, and FIG. 1(b) is a view showing the mechanism for an IDT electrode of the SAW resonator as an equivalent electrical circuit in order to analyze the physical properties of a surface acoustic wave (SAW) generated through the IDT electrode of the SAW resonator shown in FIG. 1(a).

As shown in FIG. 1(a), the SAW resonator is configured such that an interdigital transducer (IDT) electrode 200 is formed on a piezoelectric substrate 100 and a surface acoustic wave (SAW) is generated on the surface of the piezoelectric substrate 100 according to an electrical signal applied to the IDT electrode 200. In this case, as shown in (a) of FIG. 1, reflectors 110 and 120 may be provided at both ends of the IDT electrode 200 on the piezoelectric substrate 100 such that the surface acoustic wave generated by the IDT electrode 200 are reflected from the respective reflectors 110 and 120 without leaking to the outside.

The SAW resonator is very difficult to analyze because electrical energy and acoustic energy are combined with each other. In order to easily solve this problem, as shown in FIG. 1(b), the electromechanical coupling coefficient k² may be introduced to separate the acoustic energy and the electrical energy from each other such that the mechanism of the SAW at the IDT electrode can be analyzed circuitously.

Conventionally, k², which is the intrinsic constant of a piezoelectric material, may be defined theoretically using the elastic stiffness constant c, the piezoelectric stress constant e, and the dielectric permittivity ε, as represented by [Equation 1] below, and may be calculated experimentally using the acoustic wave phase velocity change ∇vₐ due to piezoelectric shorting in the IDT electrode.

$${k}^{2} ≡ \frac{{e}^{2}}{{c}^{E} {ε}^{S}} \approx 2 \vert \frac{∇ {v}_{a}}{{v}_{a}} \vert \qquad [ Equation 1 ]$$

Since k² in [Equation 1] above is the electromechanical coupling coefficient of a bulk wave, it is not suitable for SAW devices in which most of the acoustic wave exists on the surface of the piezoelectric substrate.

In order to solve the above problem, Smith in Prior Art Documents 1 and 2 above introduced the correction factor δ to newly define

$${k}_{Smith}^{2} \approx δ \cdot {k}^{2} = 2 \vert \frac{∇ {v}_{a}}{{v}_{a}} \vert \qquad [ Equation 2 ]$$

as represented by [Equation 2] below.

$${k}_{Smith}^{2}$$

$${k}_{Smith}^{2} ,$$

is suitable for SAW devices operating at hundreds of MHz or less, but if the operating frequency of the SAW devices increases to several GHz, it is not suitable due to the mass loading effect of the IDT electrode.

In order to solve this problem, Ikata in Prior Art Document 3 above modeled the phase velocity of the SAW in the IDT electrode as the ratio (τᵥ=vₒ/vₘ) of the phase velocity of the SAW in the IDT electrode without metal loading (without the fingers of the IDT electrode) to the phase velocity of the SAW in the IDT electrode with metal loading (with the fingers of the IDT electrode), taking into account the mass loading effect.

Since the electromechanical coupling coefficient is not suitable for the conventional method, the SAW device may be successfully designed by modifying the bandwidth of the SAW device, but Ikata's method also has limitations, since the mass loading effect becomes more nonlinear as the SAW operating frequency increases to several GHz.

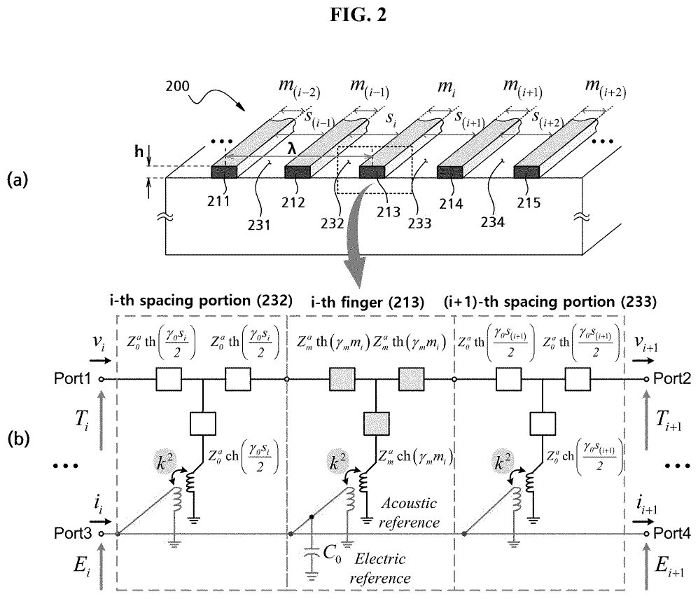

The circuit model of the IDT electrode 200 for the SAW resonator may be represented by a four-port transmission line model shown in FIG. 2.

FIG. 2(a) is an enlarged view showing the IDT electrode 200 of the SAW resonator, and FIG. 2(b) is a view showing a four-port transmission line model using an equivalent electrical circuit based on an i-th finger for analysis of the SAW by the IDT electrode shown in FIG. 2(a).

As shown in FIG. 2(a), the IDT electrode 200 includes a plurality of fingers 211 to 215 and a plurality of spacing portions 231 to 234 provided between the respective fingers, wherein reference numeral 211 indicates an (i−2)-th finger, which has a width of m(i−2), reference numeral 212 indicates an (i−1)-th finger, which has a width of m(i−1), reference numeral 213 indicates an i-th finger, which has a width of mi, reference numeral 214 indicates an (i+1)-th finger, which has a width of m₍ᵢ₊₁₎, and reference numeral 215 indicates an (i+2)-th finger, which has a width of m₍ᵢ₊₂₎.

In addition, as shown in FIG. 2(2), the width of an (i−1)-th spacing portion 231 provided between the (i−2)-th finger 211 and the (i−1)-th finger 212 is S₍ᵢ₋₁₎, the width of an i-th spacing portion 232 provided between the (i−1)-th finger 212 and the i-th finger 213 is Sᵢ, the width of an (i+1)-th spacing portion 233 provided between the i-th finger 213 and the (i+1)-th finger 214 is S₍ᵢ₊₁₎, and the width of an (i+2)-th spacing portion 234 provided between the (i+1)-th finger 214 and the (i+2)-th finger 215 is S₍ᵢ₊₂₎.

Here, 211, 213, and 215 are the fingers of the input IDT electrode, i.e., the input fingers, and 212 and 214 are the fingers of the output IDT electrode, i.e., the output fingers.

As shown in FIG. 2(a), the distance between the input fingers or the distance between the output fingers is referred to as the period λ of the IDT electrode, and half of the distance, i.e., λ/2, is referred to as the period length Lp. The symbol h shown in FIG. 2(a) indicates the thickness of each finger 211, etc.

FIG. 2(b) shows a four-port transmission line model using an equivalent electrical circuit for the i-th spacing portion 232 and the (i+1)-th spacing portion 233 around the i-th finger 213 shown in FIG. 2(a).

In order to calculate the four-port transmission line model shown in FIG. 2(b), it is necessary to determine the capacitance Co for the fingers of the IDT electrode, the phase velocities vₒ and vₘ of the SAW with and without the mass loading effect, the electromechanical coupling coefficient k², and the attenuation constant α of the SAW.

The SAW resonator design method according to the embodiment of the present invention is configured to design a SAW resonator with desired characteristics by effectively determining the above parameters.

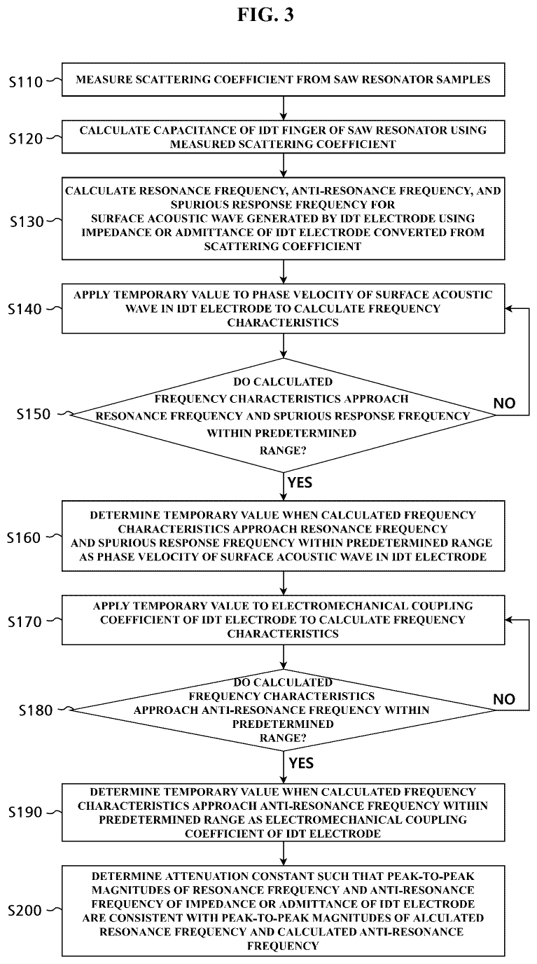

To this end, the SAW resonator design method according to the embodiment of the present invention may include steps according to the flowchart shown in FIG. 3, wherein the capacitance Co, the phase velocities vₒ and vₘ of the SAW with and without the mass loading effect, the electromechanical coupling coefficient k², and the attenuation constant α of the SAW may be effectively calculated.

The steps of the SAW resonator design method according to the embodiment of the present invention described will be described with reference to FIG. 3. First, a sample is taken for a SAW resonator to be designed, and the scattering coefficient of the SAW resonator is measured from the sample as an initial parameter (S110).

The mass loading effect of the IDT electrode varies nonlinearly according to the film-thickness ratio h/Lₚ, which is the ratio of the thickness h of the IDT electrode to the period length Lₚ of the IDT electrode shown in FIG. 2(a).

Therefore, test patterns may be manufactured while the period length Lₚ of the IDT electrode is changed in the state in which the aperture length La, the number of IDT fingers N_{IDT}, the number of reflectors N_{ref}, and the thickness h of the finger the one-port SAW resonator are not changed, and these test patterns may be used as samples. The scattering coefficient of each of the manufactured samples may be measured using VNA.

The capacitance of each finger of the IDT electrode of the SAW resonator may be calculated using the measured scattering coefficient (S120).

The admittance Yᵢₙ(ω) may be calculated using the measured scattering coefficient, as represented by [Equation 3] below.

$${Y}_{in} ( ω ) = {Y}_{0} \cdot \frac{1 - {S}_{11} ( ω )}{1 + {S}_{11} ( ω )} \qquad [ Equation 3 ]$$

$$where$$

$${Y}_{0} = 0.02 [ S ]$$

where ω is the angular frequency, and S₁₁(ω) is the scattering coefficient.

The total capacitance Cₜₒₜₐₗ of the SAW resonator may be calculated from Yᵢₙ(ω) using [Equation 4] below. Here, the frequency f for calculation is a low frequency of 100 MHz or less at which the capacitance value of the IDT electrode is stable.

$${C}_{total} = \frac{{Y}_{in} ( ω )}{ω} {\vert}_{ω = low freq .} \qquad [ Equation 4 ]$$

$$where$$

$$ω = 2 π f$$

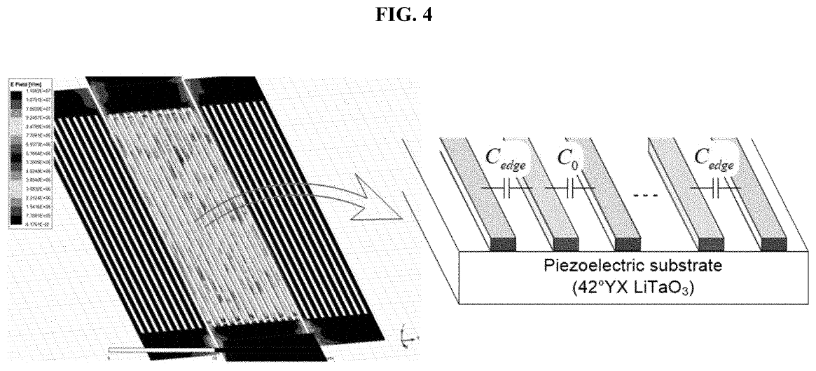

The total capacitance Cₜₒₜₐₗ may also be obtained using a commercial 3D field solver (e.g., HFSS, SONNET, or ADS). FIG. 4 shows an example of using the 3D field solver.

As shown in FIG. 4, the total capacitance Cₜₒₜₐₗ may be re-expressed as the sum of the capacitances in the IDT electrode, which may be represented by Equation 5 below.

$${C}_{total} \approx 2 {C}_{edge} + ( {N}_{IDT} - 3 ) {C}_{internal} + {C}_{parasitic} \qquad [ Equation 5 ]$$

where Cᵢₙₜₑᵣₙₐₗ is the capacitance of each of the inner fingers of the IDT electrode excluding the outmost fingers, C_{edge} is the capacitance of each of the outmost fingers of the IDT electrode, and C_{parasitic} is the parasitic capacitance.

Cᵢₙₜₑᵣₙₐₗ may be calculated from different N samples of the one-port SAW resonator, and since Cᵢₙₜₑᵣₙₐₗ and C_{edge} are almost equal, as shown in FIG. 4, the capacitance Co of the fingers of the IDT electrode of the four-port SAW transmission line model is almost equal to Cᵢₙₜₑᵣₙₐₗ and may be calculated as Cᵢₙₜₑᵣₙₐₗ.

As described above, the IDT finger capacitance may be calculated according to step S120 of FIG. 3.

Meanwhile, as shown in FIG. 3, the resonance frequency f₁, the anti-resonance frequency f₂, and the spurious response frequency f₃ for the surface acoustic wave (SAW) generated by the IDT electrode may be calculated using the impedance or the admittance of the IDT electrode converted from the scattering coefficient measured as described above, e.g., using the admittance of the IDT electrode obtained from [Equation 3] above.

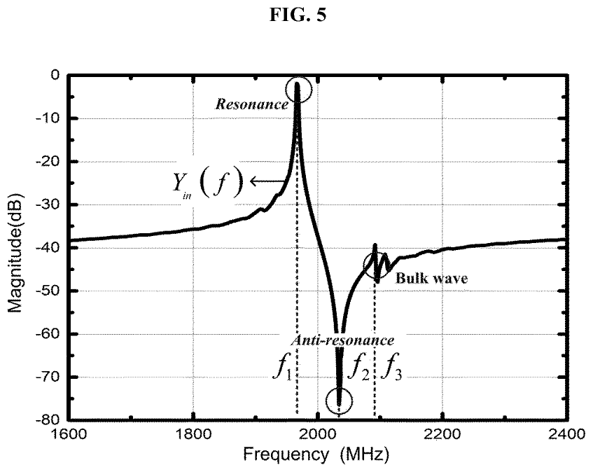

FIG. 5 is a graph showing the admittance Yᵢₙ as a function of the frequency of the IDT electrode, wherein the resonance frequency f₁, the anti-resonance frequency f₂, and the spurious response frequency f₃ are shown.

Here, the spurious response frequency f₃, which is the response frequency due to a bulk wave generated in the IDT electrode, corresponds to noise in the response characteristics of the SAW.

The response frequency due to the bulk wave acts as noise in determining the physical properties of the SAW, and thus increases the nonlinearity of the physical properties of the SAW.

In the SAW resonator design method according to the embodiment of the present invention, the spurious response frequency f₃ due to the bulk wave corresponding to the noise as described above is also considered to calculate the required parameters, and therefore it is possible to calculate more accurate physical property information of the SAW than the conventional Smith or Ikata methods.

Referring back to FIG. 3, after calculating the resonance frequency f₁, the anti-resonance frequency f₂, and the spurious response frequency f₃ for the SAW using the admittance in step S130 as described above, temporary values

$$v \frac{t e m p}{o} and v \frac{t e m p}{m}$$

are applied to the phase velocity of the surface acoustic wave (SAW) in the IDT electrode to calculate the frequency characteristics (S140), and the resonance frequency and the spurious response frequency calculated therefrom are compared with the resonance frequency f₁ and the spurious response frequency f₃ shown in FIG. 5, respectively, to determine whether the frequencies are substantially consistent, i.e., whether the frequency characteristics based on the temporary values approach the resonance frequency f₁ and the spurious response frequency f₃ within a predetermined range (S150).

The temporary values of the phase velocity may be repeatedly applied while the temporary values are changed until the frequency characteristics based on the temporary values approach the resonance frequency f₁ and the spurious response frequency f₃ within the predetermined range, and the temporary values when the frequency characteristics approach the resonance frequency and the spurious response frequency within the predetermined range may be determined as the phase velocities vₒ and vₘ of the surface acoustic wave in the IDT electrode (S160).

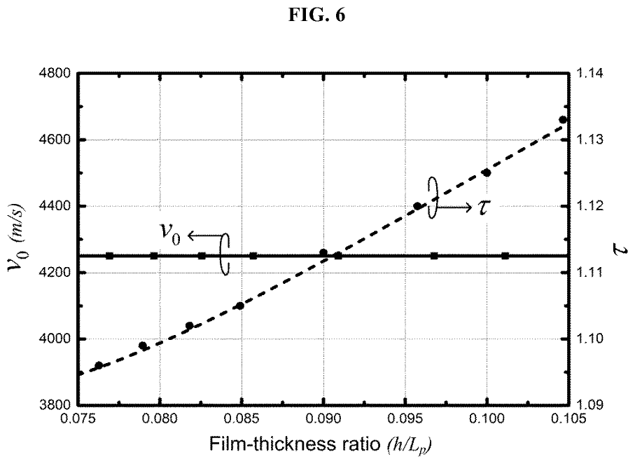

As previously described, the mass loading effect of the IDT electrode of the SAW resonator varies nonlinearly according to the film-thickness ratio h/Lₚ, which is the ratio of the thickness h of the IDT electrode to the period length Lp of the IDT electrode. FIG. 6 is a graph showing the relationship between the phase velocity vₒ and the phase velocity ratio τᵥ of the SAW without the fingers of the IDT electrode (without the mass loading effect) obtained in step S160 above for the film-thickness ratio h/Lₚ.

As shown in FIG. 6, it can be seen that the ratio (τᵥ=vₒ/vₘ) of the phase velocity vₒ of the SAW without the fingers of the IDT electrode to the phase velocity vₘ of the SAW with the fingers of the IDT electrode changes nonlinearly as the film-thickness ratio h/Lₚ changes.

Referring back to FIG. 3, after determining the phase velocities vₒ and vₘ of the SAW using the resonance frequency and the spurious response frequency as described above, steps S170 to S190 of determining the electromechanical coupling coefficient k² for the IDT electrode using the anti-resonance frequency may be performed. In the same manner as the phase velocity, the electromechanical coupling coefficient may be determined using an iterative method.

A temporary value may be applied to the electromechanical coupling coefficient of the IDT electrode to calculate the frequency characteristics of the SAW (S170), it may be determined whether the calculated frequency characteristics approach the anti-resonance frequency f₂ shown in FIG. 5 within a predetermined range (S180), the temporary value of the electromechanical coupling coefficient may be repeatedly applied while the temporary value is changed until the frequency characteristics approach the anti-resonance frequency f₂ within the predetermined range, and the temporary value when the frequency characteristics approach the anti-resonance frequency f₂ within the predetermined range may be determined as the electromechanical coupling coefficient k² of the IDT electrode (S190).

In addition, the attenuation constant α may be determined such that the peak-to-peak magnitudes of the resonance frequency and the anti-resonance frequency of the impedance or the admittance according to the phase velocity and the electromechanical coupling coefficient of the SAW determined as described above are consistent with the peak-to-peak magnitudes of the resonance frequency f₁ and the anti-resonance frequency f₂ shown in FIG. 5 (S200).

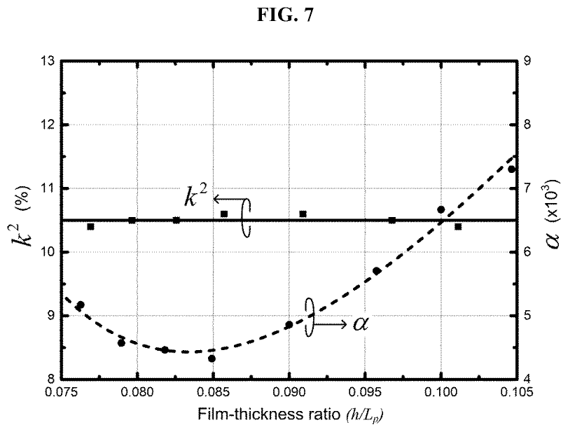

FIG. 7 is a graph showing the relationship between the electromechanical coupling coefficient k² and the attenuation constant α obtained in step S190 above for the film-thickness ratio h/Lₚ.

As shown in FIG. 7, it can be seen that the electromechanical coupling coefficient k² of the IDT electrode remains almost constant as the film-thickness ratio h/Lₚ changes, whereas the attenuation constant α changes nonlinearly as the film-thickness ratio h/Lₚ changes.

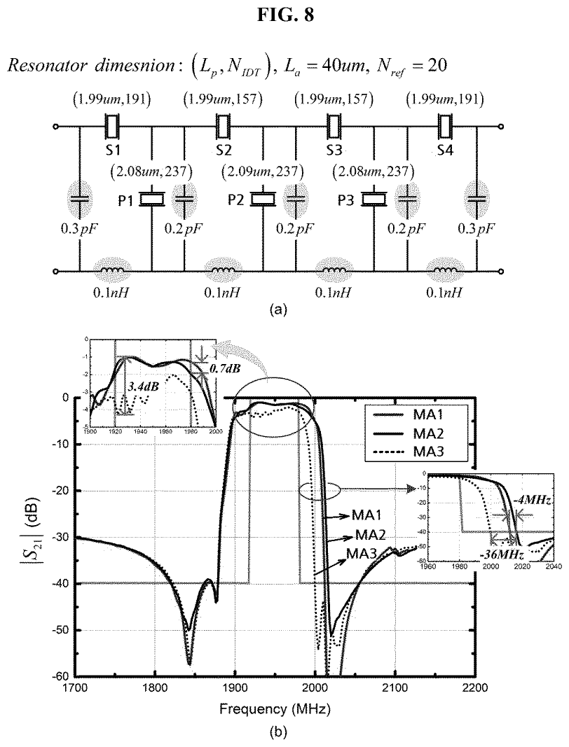

Meanwhile, FIG. 8(a) shows a 3.5-stage ladder type SAW filter including series-connected SAW resonators S1 to S4 and parallel-connected SAW resonators P1 to P3 to verify the SAW resonator design method according to the embodiment of the present invention.

The aperture length La of each of the series-connected SAW resonators S1 to S4 and the parallel-connected SAW resonators P1 to P3 is 40 μm, and when the number of reflectors N_{ref} is 20, the period length Lₚ and the number of IDT fingers N_{IDT} of each of the series-connected SAW resonators S1 to S4 and the period length Lₚ and number of IDT fingers N_{IDT} of each of the parallel-connected SAW resonators P1 to P3 are the same as shown in FIG. 8(a).

For the test SAW filter shown in FIG. 8(a), a graph of frequency versus insertion loss is calculated as shown in FIG. 8(b).

In the graph shown in FIG. 8(b), MA3, represented by the dotted line, is the graph calculated by the conventional method, MA1, represented by the red solid line, is the graph calculated by the method according to the present invention, and MA2, represented by the black solid line, is the graph according to the result simulated by measurement.

As shown in FIG. 8(b), comparing MA3 according to the conventional method, MA1 according to the present invention, and MA2 according to the measured simulation result, MA3 according to the conventional method in the passband shows a significant difference in frequency bandwidth of up to 36 MHz and insertion loss of up to 3.4 dB from MA2 according to the simulation result.

In contrast, a comparison between MA1 according to the present invention and MA2 according to the simulation results shows a small difference of up to 4 MHz in bandwidth and up to 0.7 dB in insertion loss, indicating that the results according to the present invention are quite consistent with the frequency characteristics of actual SAW filters.

Therefore, it is difficult to design an accurate SAW filter when designing the SAW filter using already known material values by conventional methods, but the method presented in the present invention enables a SAW filter to be very accurately designed even at several GHz.

### INDUSTRIAL APPLICABILITY

A SAW resonator design method according to the present invention and a computing device-readable recording medium having the same recorded thereon may be applied to software configured to perform functions by implementing a process according to the design method as an algorithm, to a computer configured to perform the functions, or to equipment for designing or manufacturing a SAW resonator or filter, and therefore the present invention has industrial applicability in the technical field of designing SAW resonators or SAW filters.

1. A SAW resonator design method using characteristic information of a SAW resonator, the SAW resonator design method comprising:
calculating feature frequency information for a surface acoustic wave generated by an IDT electrode using a scattering coefficient measured from each of SAW resonator samples;
calculating information indicative of physical properties of the surface acoustic wave in the IDT electrode using the feature frequency information; and
designing a SAW resonator from a transmission line circuit model of the surface acoustic wave using the calculated information indicative of the physical properties of the surface acoustic wave.

2. The SAW resonator design method according to claim 1, further comprising calculating a capacitance per finger of the IDT electrode using the scattering coefficient as one piece of the information indicative of the physical properties of the surface acoustic wave.

3. The SAW resonator design method according to claim 1, wherein the step of calculating the feature frequency information for the surface acoustic wave comprises calculating a resonance frequency, an anti-resonance frequency, and a spurious response frequency for the surface acoustic wave generated by the IDT electrode using an impedance or an admittance of the IDT electrode converted from the scattering coefficient.

4. The SAW resonator design method according to claim 1, wherein the step of calculating the information indicative of the physical properties of the surface acoustic wave comprises:
determining a phase velocity of the surface acoustic wave in the IDT electrode using the feature frequency information;
determining an electromechanical coupling coefficient indicative of how much electrical energy can be converted into surface acoustic wave energy from the IDT electrode using the feature frequency information; and
determining an attenuation constant of the surface acoustic wave in the IDT electrode using the feature frequency information.

5. The SAW resonator design method according to claim 3, wherein the step of calculating the information indicative of the physical properties of the surface acoustic wave comprises determining a temporary value as a value of a phase velocity indicative of the physical properties of the surface acoustic wave when frequency characteristics calculated by repeatedly applying the temporary value to the phase velocity of the surface acoustic wave in the IDT electrode while varying the temporary value approach the calculated resonance frequency and the calculated spurious response frequency within a predetermined range.

6. The SAW resonator design method according to claim 3, wherein the step of calculating the information indicative of the physical properties of the surface acoustic wave comprises determining a temporary value as a value of an electromechanical coupling coefficient indicative of the physical properties of the surface acoustic wave when frequency characteristics calculated by repeatedly applying the temporary value to the electromechanical coupling coefficient of the IDT electrode while varying the temporary value approach the calculated anti-resonance frequency within a predetermined range.

7. The SAW resonator design method according to claim 3, wherein the step of calculating the information indicative of the physical properties of the surface acoustic wave comprises determining an attenuation constant such that peak-to-peak magnitudes of the resonance frequency and the anti-resonance frequency of the impedance or the admittance of the IDT electrode are consistent with peak-to-peak magnitudes of the calculated resonance frequency and the calculated anti-resonance frequency.

8. A computing device-readable recording medium having the SAW resonator design method according to claim 1 recorded thereon.
